(19) United States
(12) Patent Application Publication
(10) Pub. No.: US 2025/0324894 A1
(43) Pub. Date: Oct. 16, 2025

(54) DISPLAY PANEL AND DISPLAY DEVICE

(71) Applicant: HKC CORPORATION LIMITED, Shenzhen (CN)

(72) Inventors: YANGLING TANG, Shenzhen (CN); Qin LIANG, Shenzhen (CN); Zhisheng XIE, Shenzhen (CN); Xiufeng ZHOU, Shenzhen (CN); Haijiang YUAN, Shenzhen (CN)

(21) Appl. No.: 19/177,694

(22) Filed: Apr. 14, 2025

(30) Foreign Application Priority Data
Apr. 15, 2024 (CN) 202410458869.4

(51) Int. Cl. H10K 59/80; H10K 59/122

(52) U.S. Cl. CPC H10K 59/873; H10K 59/122

(57) ABSTRACT

A display panel and a display device are disclosed. The display panel includes a substrate, a pixel driving layer, a light-emitting element layer, an encapsulation layer, and an encapsulation barrier dam. The pixel driving layer is arranged on the substrate. The light-emitting element layer is arranged on the pixel driving layer. The light-emitting element layer includes multiple light-emitting elements arranged in an array. The encapsulation layer is arranged on the light-emitting element layer and is configured to seal the light-emitting element layer. The encapsulation barrier dam is arranged on an outer side of the light-emitting element layer. The encapsulation barrier dam includes a first overhang structure. The first overhang structure includes a first metal layer and a first insulating layer. The first insulating layer has a width greater than that of the first metal layer.

### CROSS-REFERENCE TO RELATED APPLICATIONS

This application claims the priority and benefit of Chinese patent application number 2024104588694, titled “Display Panel and Display Device” and filed Apr. 15, 2024 with China National Intellectual Property Administration, the entire contents of which are incorporated herein by reference.

### TECHNICAL FIELD

This application relates to the field of display technology, and more particularly relates to a display panel and a display device.

### BACKGROUND

The description provided in this section is intended for the mere purpose of providing background information related to the present application but doesn't necessarily constitute prior art.

OLED (Organic Light Emitting Diode) display devices are widely used in various fields because of their light weight, wide viewing angle, fast response, low temperature resistance, high light-emitting efficiency, and the ability to produce curved flexible display screens. As mass production technology matures, OLED display panels have gradually become mainstream display panels. However, since the light-emitting devices in the OLED display panel have poor stability and are extremely sensitive to water and oxygen, water and oxygen will cause the light-emitting devices to be oxidized and fail, so that the encapsulation technology is particularly critical. The mainstream thin film encapsulation technology is to perform encapsulation by stacking multiple inorganic layers and organic layers. Since the interface between the film layers is also subject to the risk of water vapor or oxygen intrusion, an encapsulation barrier dam may be used in the non-display area of the display panel. On the one hand, it blocks the organic layer from flowing to the outside, and on the other hand, it can extend the path for water vapor or oxygen to invade from the sides.

However, due to manufacturing process reasons, the height of the encapsulation barrier dam may be insufficient, causing part of the organic layer to overflow, resulting in poor encapsulating effect.

### SUMMARY

It is therefore one purpose of this application to provide a display panel and a display device, which form an encapsulation barrier dam by utilizing an overhanging structure, thereby increasing the height of the encapsulation barrier dam and improving the encapsulating effect of the display panel.

This application discloses a display panel. The display panel includes a substrate, a pixel driving layer, a light-emitting element layer, an encapsulation layer, and an encapsulation barrier dam. The pixel driving layer is arranged on the substrate. The light-emitting element layer is arranged on the pixel driving layer. The light-emitting element layer includes a plurality of light-emitting elements arranged in an array. The encapsulation layer is arranged on the light-emitting element layer for sealing the light-emitting element layer. The encapsulation barrier dam is arranged on an outside of the light-emitting element layer. The encapsulation barrier dam includes a first overhang structure. The first overhang structure includes a first metal layer and a first insulating layer. The width of the first insulating layer is greater than the width of the first metal layer.

In some embodiments, the display panel includes a display area and a non-display area. The display panel further includes a pixel defining layer, and the pixel defining layer is arranged on the pixel driving layer. The adjacent light-emitting elements are separated by the pixel defining layer. The encapsulation barrier dam is arranged in the non-display area. The pixel defining layer extends to the non-display area to form an extension piece, and the extension piece is arranged under the encapsulation barrier dam. Under the orthographic projection on the substrate, the extension piece overlaps or coincides with the encapsulation barrier dam. The encapsulation layer includes a first inorganic layer, an organic layer, and a second inorganic layer. The organic layer is arranged on the first inorganic layer. The second inorganic layer is arranged on the organic layer. The first inorganic layer and the second inorganic layer extend from the display area to the non-display area and cover the encapsulation barrier dam. The organic layer is blocked by the encapsulation barrier dam to prevent the organic layer from spreading outward.

In some embodiments, an opening is provided in the extension piece. The first metal layer covers the extension piece and the opening, and forms a first recess corresponding to the position of the opening. The first insulating layer covers the first metal layer, and forms a second recess corresponding to the position of the first recess.

In some embodiments, the opening is a through hole. A second metal layer is disposed below the extension piece. The first metal layer is connected to the second metal layer through the opening.

In some embodiments, the light-emitting element includes a bottom electrode, a light-emitting layer, and a top electrode. The bottom electrode and the second metal layer are located in the same layer and are formed by the same manufacturing process.

In some embodiments, the display panel further includes a planarization layer, which is arranged on the pixel driving layer. In the non-display area, the second metal layer is arranged on the planarization layer, and the width of the second metal layer is smaller than the width of the planarization layer. The extension piece covers the planarization layer and the second metal layer.

In some embodiments, the display panel further includes a second overhang structure, which is arranged in the display area and located on the pixel defining layer; the first overhang structure and the second overhang structure are formed by the same manufacturing process.

In some embodiments, the pixel defining layer includes a plurality of openings. The first metal layer defines a plurality of first recesses in the areas corresponding to the openings. The first insulating layer defines a plurality of second recesses in the areas corresponding to the plurality of first recesses.

In some embodiments, the encapsulation barrier dam includes a first barrier dam and a second barrier dam. The first barrier dam is arranged on a side of the second barrier dam facing towards the display area. The height of the second barrier dam is higher than the height of the first barrier dam.

This application further discloses a display device, including a driving circuit and the above-mentioned display panel, wherein the driving circuit is used to drive the display panel to display.

In this application, the encapsulation barrier dam is formed by using the first overhang structure, and the height of the encapsulation barrier dam is increased by using the height of the first overhang structure. As such, on the one hand, the organic layer in the encapsulation layer is prevented from overflowing. On the other hand, the width of the first insulating layer located at the upper part of the first overhang structure is greater than the width of the first metal layer located at the lower part, so that the inorganic layer has a more tortuous path on the first overhang structure, thereby extending the path for water vapor or oxygen to invade. Furthermore, the first overhang structure is a key structure used in the maskless evaporation technology, and can be processed synchronously with other overhang structures in the display panel. Without adding additional processes, better encapsulation is achieved, and no additional costs are added.

### BRIEF DESCRIPTION OF DRAWINGS

The accompanying drawings are used to provide a further understanding of the embodiments according to this application, and constitute a part of the specification. They are used to illustrate the embodiments according to this application, and explain the principles of this application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel of a first embodiment of this application.

FIG. 2 is a schematic diagram of a display panel of a second embodiment of this application.

FIG. 3 is a schematic diagram of another display panel of the second embodiment of this application.

FIG. 4 is a schematic diagram of a display panel of a third embodiment of this application.

FIG. 5 is a schematic diagram of another display panel of the third embodiment of this application.

FIG. 6 is a schematic diagram of a display device of this application.

In the drawings: 100, display panel; 101, display area; 102, non-display area; 110, substrate; 120, pixel driving layer; 121, second insulating layer; 130, light-emitting element; 131, bottom electrode; 132, light-emitting layer; 133, top electrode; 134, second metal layer; 140, pixel defining layer; 141, extension piece; 141a, opening; 150, encapsulation layer; 151, first inorganic layer; 152, organic layer; 153, second inorganic layer; 160, encapsulation barrier dam; 161, first overhang structure; 161a, first metal layer; 161b, first insulating layer; 162, second overhang structure; 163, first recess; 164, second recess; 170, first barrier dam; 171, second barrier dam; 172, third overhang structure; 172a, third metal layer; 172b, third insulating layer; 180, planarization layer; 200, display device; 210, driving circuit.

### DETAILED DESCRIPTION OF EMBODIMENTS

It should be understood that the terms used herein, the specific structures and functional details disclosed therein are merely representative for describing some specific embodiments, but this application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in this application can be understood depending on specific contexts.

This application will be described in detail below with reference to the accompanying drawings and some optional embodiments.

FIG. 1 is a schematic diagram of a display panel of a first embodiment of this application. As shown in FIG. 1, this application discloses a display panel 100. The display panel 100 includes a substrate 110, a pixel driving layer 120, a light-emitting element layer, an encapsulation layer 150, and an encapsulation barrier dam 160. The pixel driving layer 120 is arranged on the substrate 110. The light-emitting element layer is arranged on the pixel driving layer 120, and includes a plurality of light-emitting elements 130 arranged in an array. The encapsulation layer 150 is arranged on the light-emitting element layer, and is used to seal the light-emitting element layer. The encapsulation barrier dam 160 is arranged on an outside of the light-emitting element layer. The encapsulation barrier dam 160 includes a first overhang structure 161. The first overhang structure 161 includes a first metal layer 161a and a first insulating layer 161b. The width of the first insulating layer 161b is greater than the width of the first metal layer 161a.

In this application, the encapsulation barrier dam 160 is formed by using the first overhang structure 161, and the height of the encapsulation barrier dam 160 is increased by using the height of the first overhang structure 161. As such, on the one hand, the organic layer 152 in the encapsulation layer 150 is prevented from overflowing. On the other hand, the width of the first insulating layer 161b located at the upper part of the first overhang structure 161 is greater than the width of the first metal layer 161a located at the lower part, so that the inorganic layer has a more tortuous path on the first overhang structure 161, thereby extending the path for water vapor or oxygen to invade. Furthermore, the first overhang structure 161 is a key structure used in the maskless evaporation technology, and can be processed synchronously with other overhang structures in the display panel 100. Without adding additional processes, better encapsulation is achieved, and no additional costs are added.

The maskless evaporation technology is to form an overhang structure on the pixel defining layer 140 in the display area 101. The upper width of the overhang structure is greater than the lower width, and so it can also be called an eaves structure. Under this structure, the light-emitting element 130 may be formed without a mask. Furthermore, the lower part of the overhang structure is formed of a metal material, which has conductive properties and can connect the cathodes of multiple light-emitting elements 130 to form a whole-surface cathode wiring to reduce the resistance drop of the cathode. The first overhang structure 161 of this application may be formed by the same manufacturing procedure as the overhang structure(s) inside the display panel 100.

The substrate 110 in this embodiment may be a flexible substrate or a glass substrate, etc. The pixel driving layer 120 is formed on the substrate 110. The pixel driving layer 120 may be formed by stacking multiple metal layers and multiple insulating layers. The main devices formed include but are not limited to thin film transistors, metal wiring, transparent wiring, etc. that are used for driving the light-emitting elements 130 for display. Specifically, the display panel 100 includes a display area 101 and a non-display area 102. The display panel 100 includes a pixel defining layer 140. The light-emitting element layer and the pixel defining layer 140 are each arranged on the pixel driving layer 120. The pixel defining layer 140 includes a plurality of openings, and the plurality of light-emitting elements 130 are respectively arranged in the plurality of openings. The adjacent light-emitting elements 130 are separated by the pixel defining layer 140.

In the display area 101, the display panel 100 includes a plurality of second overhang structures 162, which are all arranged on the pixel defining layer 140. The second overhang structures 162 are respectively arranged around the position of each opening. The second overhang structure 162 has the same shape as the first overhang structure 161, and also includes a metal layer arranged at the bottom and an insulating layer arranged at the top.

The main function of the second overhang structure 162 in this scheme is that in the process of forming the light-emitting element 130, a mask plate is no longer required, and the light-emitting element 130 can be directly formed by an inkjet printing device. In this process, due to the effect of the overhang structure, the mask plate can be omitted. The second overhang structure 162 and the first overhang structure 161 are formed by the same manufacturing procedure.

Specifically, the light-emitting element 130 includes a bottom electrode 131, a light-emitting layer 132, and a top electrode 133. The bottom electrode 131 is formed before the pixel defining layer 140 is formed. The light-emitting layer 132 and the top electrode 133 are formed by maskless evaporation technology. The light-emitting layer 132 may include a multi-layer film structure, and light-emitting elements 130 of different colors have different light-emitting layer materials.

The encapsulation layer 150 is arranged on the light-emitting element 130 and the second overhang structure 162. The encapsulation layer 150 may include a first inorganic layer 151, an organic layer 152, and a second inorganic layer 153. The organic layer 152 is arranged on the first inorganic layer 151. The second inorganic layer 153 is arranged on the organic layer 152. The first inorganic layer 151 and the second inorganic layer 153 extend from the display area 101 to the non-display area 102 and cover the encapsulation barrier dam 160. The organic layer 152 is blocked by the encapsulation barrier dam 160 to prevent the organic layer 152 from spreading outward. The first inorganic layer 151 and the second inorganic layer 153 are arranged on the encapsulation barrier dam 160, and the first inorganic layer 151 and the second in-organic layer 153 continue to extend to the side of the encapsulation barrier dam 160 facing away from the light-emitting element layer.

Specifically, the pixel defining layer 140 extends toward the non-display area 102 to form an extension piece 141. The extension piece 141 is disposed below the encapsulation barrier dam 160 to raise the encapsulation barrier dam 160. The extension piece 141 does not require an additional manufacturing process, and the extension piece 141 and the pixel defining layer 140 can be formed by the same manufacturing process. After the encapsulation barrier dam 160 is raised by the extension piece 141, the blocking ability with regards to the organic layer 152 can be greatly increased.

In this embodiment, on the orthographic projection onto substrate 110, the width of the extension piece 141 is greater than the width of the first overhang structure 161. In this solution, the width of the extension piece 141 is increased, the stability of the bottom film layer is increased, and the sides of the extension piece 141 and the first overhang structure 161 form a more tortuous film structure, reducing the possibility of water vapor intrusion.

However, the extension piece 141 and the pixel defining layer 140 are formed by the same manufacturing process, and the material of the pixel defining layer 140 may be an insulating organic or inorganic film layer, while the lower part of the first overhang structure 161 is a metal material, so that the first metal layer 161a above the extension piece 141 is prone to sliding or film rupture due to the poor adhesion between the two. In this regard, this application further makes a series of improvements to the extension piece 141.

In this embodiment, the height of the encapsulation barrier dam 160 is increased by utilizing the heights of the extension piece 141 and the first overhang structure 161. In the process of preventing the organic layer 152 in the encapsulation layer 150 from overflowing outward, the blocking capability with respect to the organic layer 152 can be greatly increased. Furthermore, by using a relatively wider extension piece 141, a relatively narrower first metal layer 161a, and a relatively wider first insulating layer 161b, the inorganic layer has a more tortuous path on the sides of the extension piece 141 and the first overhang structure 161, thereby extending the path for water vapor or oxygen to invade. The extension piece 141 and the first overhang structure 161 do not require additional manufacturing processes. The extension piece 141 and the pixel defining layer 140 can be formed by the same manufacturing process. The first overhang structure 161 and the second overhang structure 162 can be formed by the same manufacturing process. Without adding additional costs, the encapsulating effect of the display panel 100 is improved.

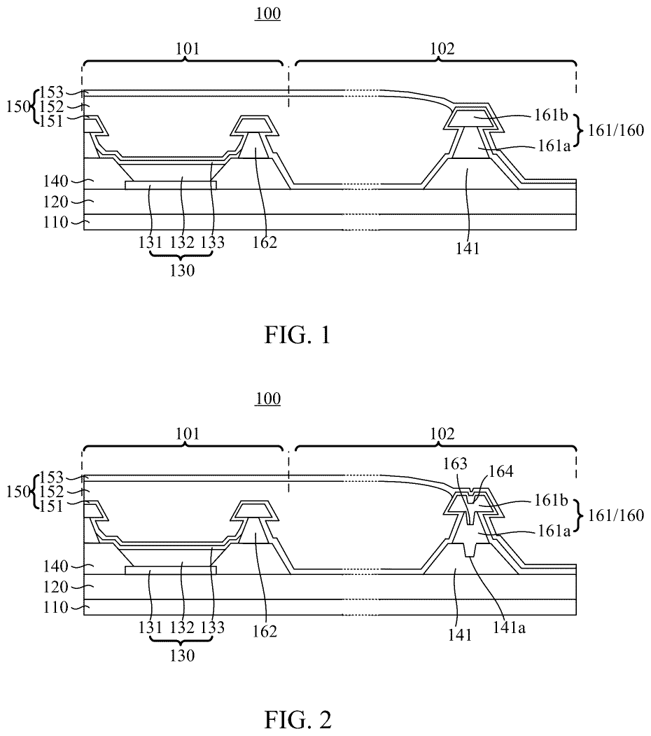

FIG. 2 is a schematic diagram of a display panel of a second embodiment of this application. As shown in FIG. 2, this application further discloses a display panel 100. The structure of the display panel 100 of the present embodiment is basically the same as that of the display panel 100 of the first embodiment described above. On the basis of the above structure, an opening 141a is further defined in the extension piece 141.

Specifically, the extension piece 141 is defined with an opening 141a. The first metal layer 161a covers the extension piece 141 and the opening 141a, and defines a first recess 163 corresponding to the position of the opening 141a. The first insulating layer 161b covers the first metal layer 161a, and defines a second recess 164 corresponding to the position of the first recess 163.

In this embodiment, an opening 141a is defined in one side of the extension piece 141 facing towards the first metal layer 161a, so that in the process of forming the first metal layer 161a, due to the existence of the opening 141a, part of the first metal layer 161a forms a protrusion at the position of the opening 141a, so that the contact area of the film layer of the first metal layer 161a is increased, and so the adhesion between the extension piece 141 and the first overhang structure 161 is increased. The fitting between the protrusion and the opening 141a can prevent the first overhang structure 161 from sliding off the extension piece 141 to a certain extent, thereby enhancing the stability of the first overhang structure 161.

Specifically, the opening 141a in this embodiment includes but is not limited to one opening 141a in one extension piece 141, and multiple openings 141a may also be defined. In a cross-sectional view of the display panel 100 from the non-display area 102 to the display area 101, the pixel defining layer 140 includes a plurality of openings 141a along the width direction of the extension piece 141. The first metal layer 161a defines a plurality of first recesses 163 in the regions corresponding to the openings 141a respectively. The first insulating layer 161b defines a plurality of second recesses 164 in the regions corresponding to the first recesses 163 respectively. In this solution, by setting a plurality of openings 141a, the contact area of the film interface between the first overhang structure 161 and the extension piece 141 is increased, so that the adhesion of the first overhang structure 161 is enhanced. Furthermore, due to the setting of the opening 141a, a second recess 164 is formed in the surface of the first insulating layer 161b, especially when multiple openings 141a are set, multiple second recesses 164 are also formed. As such, the surface of the first insulating layer 161b has an uneven film interface. The first inorganic layer 151 is formed on the first overhang structure 161, and so has a tortuous film interface, which further improves the ability to prevent water vapor or oxygen.

Of course, the multiple openings 141a described in this embodiment refer to the direction from the light-emitting element 130 to the extension piece 141, that is, the multiple openings 141a are arranged in the width direction of the extension piece 141. On the orthographic projection onto the substrate 110, the extension piece 141 is arranged around the display area 101, and so the extension direction of the extension piece 141 is the length direction of the extension piece 141. In the length direction of the extension piece 141, the opening 141a may be a slot, and the extension direction of the slot is consistent with the extension direction of the extension piece 141.

Specifically, the opening 141a in this embodiment may be a through hole or a blind hole. When the thickness of the pixel defining layer 140 is relatively thick, a blind hole solution may be selected, and when the pixel defining layer 140 is relatively thin, a through hole solution may be selected. The slot may be a through slot or a blind slot.

In this embodiment, at least two encapsulation barrier dams 160 may be provided, for example, the encapsulation barrier dam 160 may include a first barrier dam and a second barrier dam, where the first barrier dam and the second barrier dam each adopt the encapsulation barrier dam 160 of the extension piece 141 and the first overhang structure 161. By providing two or more encapsulation barrier dams 160, the barrier capability of the encapsulation barrier dam 160 for the organic layer 152 can be enhanced, and the stacking area of the first inorganic layer 151 and the second inorganic layer 153 can be increased, forming a more tortuous water vapor or oxygen invasion path, making it more difficult for water vapor or oxygen to invade the inside the display panel 100.

It is understandable that the solution of adding two or more encapsulation barrier dams 160 in this embodiment does not mean that the encapsulating effect of a single encapsulation barrier dam 160 is poor, but on the basis of adding the encapsulation barrier dams 160, a better encapsulating effect will be achieved. For the narrow-bezel display panel 100, it may be designed depending on actual conditions.

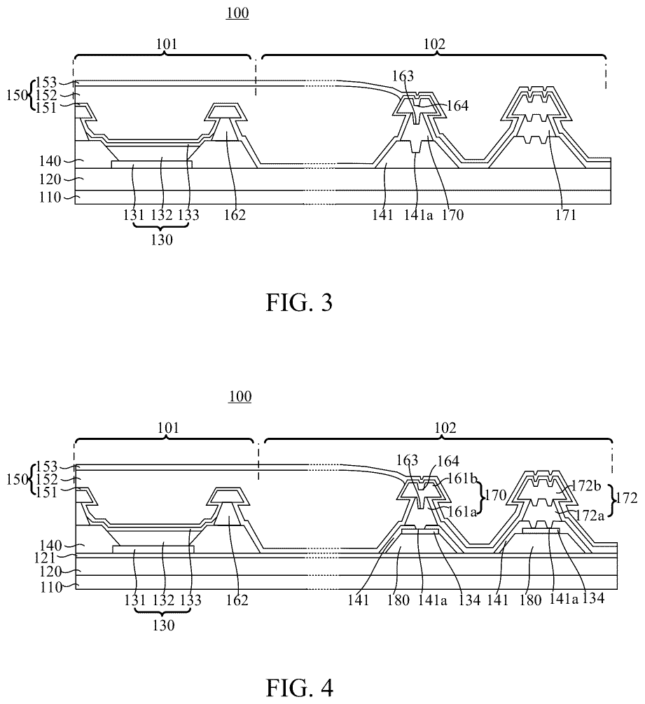

FIG. 3 is a schematic diagram of another display panel of the second embodiment of this application. In this embodiment, the first barrier dam 170 is arranged on the side of the second barrier dam 171 facing towards the display area 101. The height of the second barrier dam 171 is higher than the height of the first barrier dam 170. In this solution, by setting the heights of the first barrier dam 170 and the second barrier dam 171 to be different, a better encapsulating effect can be achieved.

In this solution, in addition to setting the first barrier dam 170 and the second barrier dam 171 to have different film layer heights, when the film layer thicknesses of the first barrier dam 170 and the second barrier dam 171 are consistent, that is, when they are formed by the same manufacturing process, the film layer thicknesses below the first barrier dam 170 and the second barrier dam 171 may be improved to make the heights of the first barrier dam 170 and the second barrier dam 171 inconsistent, which will be specifically described in the next embodiment.

In this embodiment, the height of the encapsulation barrier dam 160 is increased by using the heights of the extension piece 141 and the first overhang structure 161, so as to prevent the organic layer 152 in the encapsulation layer 150 from overflowing. Furthermore, by setting the opening 141a in the surface of the extension piece 141, the adhesion between the first overhang structure 161 and the extension piece 141 is increased, and the possibility of the first overhang structure 161 peeling off from the extension piece 141 is reduced. Furthermore, due to the setting of the opening 141a, a second recess 164 is formed in the surface of the first insulating layer 161b, and in particular, when multiple openings 141a are set, multiple second recesses 164 are also formed. As such, the surface of the first insulating layer 161b has an uneven film interface. The first inorganic layer 151 is formed on the first overhang structure 161, and so has a tortuous film interface, which further improves the ability to prevent water vapor or oxygen. On the other hand, by combining the first barrier dam 170 and the second barrier dam 171, the inorganic layer has a relatively tortuous path on the side of the extension piece 141 and the first overhang structure 161, thereby extending the path for water vapor or oxygen to invade. Without adding extra costs, the encapsulating effect of the display panel 100 is improved.

FIG. 4 is a schematic diagram of a display panel of a third embodiment of this application. As shown in FIG. 4, this application further discloses a schematic diagram of a display panel 100. Based on the above-mentioned first and second embodiments, the present embodiment further adds a second metal layer 134 and a planarization layer 180 below the extension piece 141.

Specifically, the second metal layer 134 is disposed below the extension piece 141. The first metal layer 161a is connected to the second metal layer 134 through the opening 141a.

In this solution, the second metal layer 134 may be connected to the first metal layer 161a through the opening 141a. Since the first metal layer 161a and the second metal layer 134 are both made of metal materials, the adhesion between the first metal layer 161a and the second metal layer 134 is improved, thereby preventing peeling from occurring in subsequent manufacturing processes such as evaporation or etching, thereby improving the encapsulating effect of the display panel 100 and improving the quality of the display panel 100.

The second metal layer 134 in this embodiment may form a peripheral routing wiring used for crack detection or capacitance detection wiring, etc., for detecting the encapsulation condition of the encapsulation barrier dam 160. In particular, when the lower part of the first over-hang structure 161 used as the encapsulation barrier dam 160 in this application is made of a metal material, by detecting the peripheral wiring surrounded by the second metal layer 134, it can be determined whether the first metal layer 161a in the first overhang structure 161 is cracked or corroded in the area where the encapsulation barrier dam 160 is located, so that the manufacturing process of forming an additional metal detection line can be eliminated.

As for the display area 101, the second metal layer 134 in this embodiment can be formed through the same manufacturing process as the bottom electrode 131 and the second metal layer 134 of the light-emitting element 130 in the display area 101, so as to be formed in the same film layer. The second metal layer 134 is disposed below the extension piece 141.

Furthermore, the display panel 100 further includes a planarization layer 180, which is disposed on the pixel driving layer 120. The uppermost layer of the pixel driving layer 120 may include a second insulating layer 121, and the second insulating layer 121 may be formed of a silicon nitride material. The planarization layer 180 extends from the display area 101 to the non-display area 102. In the non-display area 102, the second metal layer 134 is arranged on the planarization layer 180, and the width of the second metal layer 134 is smaller than the width of the planarization layer 180. The extension piece 141 covers the planarization layer 180 and the second metal layer 134.

In this embodiment, the planarization layer 180 is further disposed below the extension piece 141. The extension piece 141 is partly in direct contact with the surface of the planarization layer 180. The extension piece 141 is also disposed to cover both sides of the planarization layer 180 and is in direct contact with the second insulating layer 121 in the pixel driving layer 120. The extension piece 141 may be formed of the same material as the second insulating layer 121 to improve the adhesion between the extension piece 141 and the second insulating layer 121, thereby improving the adhesion of the first overhang structure 161.

It is worth mentioning that, for the area where the encapsulation barrier dam 160 of the non-display area 102 is located, the extension piece 141 and the planarization layer 180 are only arranged under the first overhang structure 161. When the first barrier dam 170 and the second barrier dam 171 are disposed, the extension piece 141 and the planarization layer 180 are disposed only below the first barrier dam 170 and the second barrier dam 171.

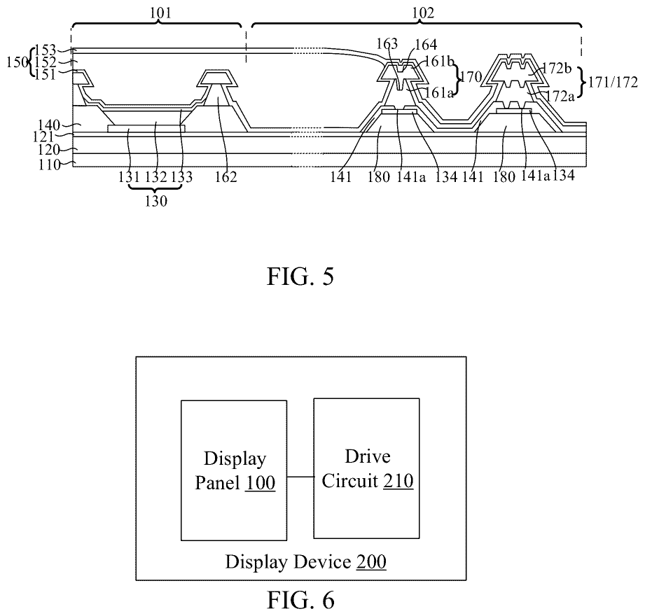

FIG. 5 is a schematic diagram of another display panel of the third embodiment of this application. The extension piece 141 between the first barrier dam 170 and the second barrier dam 171 may also be retained. That is, the extension piece of the first barrier dam is directly connected to the extension piece of the second barrier dam to increase the contact area between the extension piece 141 and the second insulating layer 121, and further enhance the adhesion between the extension piece 141 and the second insulating layer 121.

The encapsulation barrier dam 160 includes a first barrier dam 170 and a second barrier dam 171. The first barrier dam 170 is disposed on a side of the second barrier dam 171 facing towards the display area 101. The height of the second barrier dam 171 is higher than the height of the first barrier dam 170. In this embodiment, the thickness of the planarization layer 180 below the first barrier dam 170 may be made smaller than the thickness of the planarization layer 180 below the second barrier dam 171 during the etching process, so that the height of the second barrier dam 171 is higher than the height of the first barrier dam 170.

In this embodiment, the height of the encapsulation barrier dam 160 is increased by using the heights of the extension piece 141, the planarization layer 180, the second metal layer 134, and the first overhang structure 161. On the one hand, the organic layer 152 in the encapsulation layer 150 is prevented from overflowing outward, and furthermore the adhesion between the first overhang structure 161 and the extension piece 141 is increased by setting the opening 141a in the surface of the extension piece 141, thereby reducing the possibility of the first overhang structure 161 peeling off from the extension piece 141. Furthermore, due to the setting of the opening 141a, a second recess 164 is formed in the surface of the first insulating layer 161b, and in particular, when multiple openings 141a are set, multiple second recesses 164 are also formed. As such, the surface of the first insulating layer 161b has an uneven film interface. The first inorganic layer 151 is formed on the first overhang structure 161, and so has a tortuous film interface, which further improves the ability to prevent water vapor or oxygen. On the other hand, by combining the first barrier dam 170 and the second barrier dam 171, the inorganic layer has a relatively tortuous path on the side of the extension piece 141 and the first overhang structure 161, thereby extending the path for water vapor or oxygen to invade. Without adding extra costs, the encapsulating effect of the display panel 100 is improved.

FIG. 6 is a schematic diagram of a display device of this application. As shown in FIG. 6, this application discloses a display device. The display device 200 includes a driving circuit 210 and any one of the display panels 100 in the above-mentioned embodiments 1, 2, and 3. The driving circuit 210 is used to drive the display panel 100 for display.

It should be noted that the inventive concept of this application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of this application with reference to some specific optional implementations, but it cannot be determined that the specific implementation of this application is limited to these implementations. For those having ordinary skill in the technical field to which this application pertains, several deductions or substitutions may be made without departing from the concept of this application, and all these deductions or substitutions should be regarded as falling within the scope of protection of this application.

What is claimed is:

1. A display panel, comprising:
a substrate;
a pixel driving layer, disposed on the substrate;
a light-emitting element layer, disposed on the pixel driving layer and comprising a plurality of light-emitting elements arranged in an array;
an encapsulation layer, disposed on the light-emitting element layer and configured to seal the light-emitting element layer; and
an encapsulation barrier dam, disposed on an outer side of the light-emitting element layer;
wherein the encapsulation barrier dam comprises a first overhang structure, wherein the first overhang structure comprises a first metal layer and a first insulating layer disposed on the first metal layer; wherein the first insulating layer has a width that is greater than a width of the first metal layer.

2. The display panel as recited in claim 1, wherein the display panel comprises a display area and a non-display area; wherein the display panel further comprises a pixel defining layer arranged on the pixel driving layer, and wherein adjacent light-emitting elements are separated by the pixel defining layer;
wherein the encapsulation barrier dam is arranged in the non-display area;
wherein the pixel defining layer extends to the non-display area to form an extension piece, which is arranged under the encapsulation barrier dam; wherein an orthographic projection of the extension piece on the substrate overlaps or coincides with an orthographic projection of the encapsulation barrier dam on the substrate;
wherein the encapsulation layer comprises a first inorganic layer, an organic layer, and a second inorganic layer; wherein the organic layer is arranged on the first inorganic layer, wherein the second inorganic layer is arranged on the organic layer, wherein the first inorganic layer and the second inorganic layer extend from the display area to the non-display area and cover the encapsulation barrier dam, wherein the organic layer is blocked by the encapsulation barrier dam to prevent the organic layer from spreading outward.

3. The display panel as recited in claim 2, wherein there is defined at least one opening in the extension piece; wherein the first metal layer covers the extension piece and the at least one opening, and defines a first recess corresponding to a position of each of the at least one opening; wherein the first insulating layer covers the first metal layer, and defines a second recess corresponding to a position of each first recess.

4. The display panel as recited in claim 3, wherein each of the at least one opening is a through hole, wherein there is disposed a second metal layer under the extension piece, wherein the first metal layer is connected to the second metal layer through the at least one opening.

5. The display panel as recited in claim 4, wherein each of the plurality of light-emitting elements comprises a bottom electrode, a light-emitting layer, and a top electrode; wherein the bottom electrode and the second metal layer are disposed in a same layer and are formed in a same manufacturing process.

6. The display panel as recited in claim 4, further comprising a planarization layer arranged on the pixel driving layer; wherein in the non-display area, the second metal layer is arranged on the planarization layer, and wherein the second metal layer has a width that is smaller than a width of the planarization layer, and wherein the extension piece is disposed to cover the planarization layer and the second metal layer.

7. The display panel as recited in claim 3, further comprising a second overhang structure arranged in the display area and on the pixel defining layer; wherein the first overhang structure and the second overhang structure are formed in a same manufacturing process.

8. The display panel as recited in claim 3, wherein the extension piece comprises a plurality of openings, wherein the first metal layer defines a plurality of first recesses in positions corresponding to the plurality of openings, respectively, and wherein the first insulating layer defines a plurality of second recesses in positions corresponding to the plurality of first recesses, respectively.

9. The display panel as recited in claim 3, wherein the encapsulation barrier dam comprises a first barrier dam and a second barrier dam, wherein the first barrier dam is arranged on a side of the second barrier dam facing towards the display area;
wherein the second barrier dam has a height that is greater than a height of the first barrier dam.

10. The display panel as recited in claim 9, wherein the extension piece under the first barrier dam is connected to the extension piece under the second barrier dam.

11. The display panel as recited in claim 9, wherein the first barrier dam comprises a first overhang structure, wherein the second barrier dam comprises a third overhang structure, wherein the third overhang structure comprises a third metal layer and a third insulating layer, wherein the third insulating layer has a width that is greater than a width of the third metal layer, and wherein the third insulating layer is disposed on the third metal layer.

12. The display panel as recited in claim 9, wherein the first metal layer is disposed to cover the extension piece below the first overhang structure and the at least one opening below the first overhang structure, and wherein the first metal layer defines a first recess corresponding to a position of each of the at least one opening below the first overhang structure;
wherein the first insulating layer is disposed to cover the first metal layer and defines a second recess corresponding to a position of each first recess of the first overhang structure;
wherein there is defined at least one opening in the extension piece below the third overhang structure; wherein the third metal layer is disposed to cover the extension piece below the third overhang structure and the at least one opening below the third overhang structure, and wherein the third overhang structure defines a first recess corresponding to a position of the at least one opening below the third overhang structure;
wherein the third insulating layer is disposed to cover the third metal layer, and wherein the third insulating layer defines a second recess corresponding to a position of the at least one opening below the third overhang structure.

13. The display panel as recited in claim 12, wherein a number of the at least one first recess in the third overhang structure is greater than a number of the at least one first recess in the first overhang structure.

14. A display device, comprising a display panel and a driving circuit used to drive the display panel to display;
wherein the display panel comprises a substrate, a pixel driving layer, a light-emitting element layer, an encapsulation layer, and an encapsulation barrier dam; wherein the pixel driving layer is arranged on the substrate;
wherein the light-emitting element layer is arranged on the pixel driving layer and comprises a plurality of light-emitting elements that are arranged in an array; wherein the encapsulation layer is arranged on the light-emitting element layer and is configured to seal the light-emitting element layer; wherein the encapsulation barrier dam is arranged on an outer side of the light-emitting element layer;
wherein the encapsulation barrier dam comprises a first overhang structure, wherein the first overhang structure comprises a first metal layer and a first insulating layer, wherein the first insulating layer has a width that is greater than a width of the first metal layer.

15. The display device as recited in claim 14, wherein the display panel comprises a display area and a non-display area; wherein the display panel further comprises a pixel defining layer arranged on the pixel driving layer, and wherein adjacent light-emitting elements are separated by the pixel defining layer; wherein the encapsulation barrier dam is arranged in the non-display area;
wherein the pixel defining layer extends to the non-display area to form an extension piece, which is arranged under the encapsulation barrier dam; wherein an orthographic projection of the extension piece on the substrate overlaps or coincides with an orthographic projection of the encapsulation barrier dam on the substrate;
wherein the encapsulation layer comprises a first inorganic layer, an organic layer, and a second inorganic layer; wherein the organic layer is arranged on the first inorganic layer, wherein the second inorganic layer is arranged on the organic layer, wherein the first inorganic layer and the second inorganic layer extend from the display area to the non-display area and cover the encapsulation barrier dam, wherein the organic layer is blocked by the encapsulation barrier dam to prevent the organic layer from spreading outward.

16. The display device as recited in claim 15, wherein there is defined at least one opening in the extension piece; wherein the first metal layer covers the extension piece and the at least one opening, and defines a first recess corresponding to a position of each of the at least one opening; wherein the first insulating layer covers the first metal layer, and defines a second recess corresponding to a position of each first recess.

17. The display device as recited in claim 16, wherein each of the at least one opening is a through hole, wherein there is disposed a second metal layer under the extension piece, wherein the first metal layer is connected to the second metal layer through the at least one opening.

18. The display device as recited in claim 17, wherein each of the plurality of light-emitting elements comprises a bottom electrode, a light-emitting layer, and a top electrode, wherein the bottom electrode and the second metal layer are disposed in a same layer and are formed in a same manufacturing process.

19. The display device as recited in claim 17, wherein the display panel further comprises a planarization layer arranged on the pixel driving layer; wherein in the non-display area, the second metal layer is arranged on the planarization layer, and wherein the second metal layer has a width that is smaller than a width of the planarization layer, and wherein the extension piece is disposed to cover the planarization layer and the second metal layer.

20. The display device as recited in claim 16, wherein the display panel further comprises a second overhang structure arranged in the display area and on the pixel defining layer; wherein the first overhang structure and the second overhang structure are formed in a same manufacturing process.
